(19) United States
(12) Patent Application Publication
(10) Pub. No.: US 2026/0321943 A1
(43) Pub. Date: Oct. 15, 2026

(54) BALUN AND FRONT-END CIRCUIT

(71) Applicant: Murata Manufacturing Co., Ltd., Magaokakyo-shi (JP)

(72) Inventors: Kenji TAHARA, Nagaokakyo-shi (JP); Kae YAMAMOTO, Nagaokakyo-shi (JP)

(21) Appl. No.: 19/466,606

(22) Filed: Feb. 2, 2026

Related U.S. Application Data
(63) Continuation of application No. PCT/JP2024/028012, filed on Aug. 8, 2024.

(30) Foreign Application Priority Data
Aug. 22, 2023 (JP) 2023-134758

(51) Int. Cl. H01P 1/00; H03F 3/24

(52) U.S. Cl. CPC H01P 1/00; H03F 3/245; H03F 2200/451

(57) ABSTRACT

There are included: a dielectric substrate having a first surface and a second surface facing each other; a ground electrode formed on the first surface; an unbalanced terminal formed on the second surface; a pair of balanced terminals including a first balanced terminal formed on the second surface; a main line formed on the second surface and having one end connected to the unbalanced terminal and another end being open; a first sub line formed on the second surface and having one end connected to the first balanced terminal; and a second sub line formed on the second surface and having one end connected to the first balanced terminal. The first sub line has another end connected to the ground electrode through a first via and is disposed between the main line and the second sub line.

### CROSS REFERENCE TO RELATED APPLICATION

This is a continuation of International Application No. PCT/JP2024/028012 filed on Aug. 6, 2024 which claims priority from Japanese Patent Application No. 2023-134758 filed on Aug. 22, 2023. The contents of these applications are incorporated herein by reference in their entireties.

### BACKGROUND OF THE DISCLOSURE

### Field of the Disclosure

The present disclosure relates to a balun that converts signals between an unbalanced line and a balanced line and, more specifically, to a structure for improving characteristics in the balun.

### DESCRIPTION OF THE RELATED ART

As a transformer used for mutual conversion between unbalanced and balanced signals, there is a balun. Balanced signals are a pair of signals with equal amplitude and opposite phases to each other. The balanced signals are used in a differential amplifier circuit or antenna and are insusceptible to noise. On the other hand, an unbalanced signal is a signal used in a transmission system in which a change in potential with respect to a ground electrode is transmitted. The unbalanced signal is less expensive than balanced signals but is more susceptible to noise than balanced signals.

Japanese Unexamined Patent Application Publication No. 2017-158174 discloses a Marchand balun using a coupled line in which two lines connected to respective balanced terminals and having a length of a quarter of a wavelength λ (λ/4) are coupled to a line connected to an unbalanced terminal and having a length of λ/2.

As a transformer other than a balun that performs mutual conversion between unbalanced and balanced signals, there is an MCT (Magnetic Coupled Transformer) element using magnetic field coupling between a primary transformer and a secondary transformer. Typically, the sizes of an MCT element and a Marchand balun are determined in accordance with the length of a wavelength. In the MCT element, a shorter line than a line used in the Marchand balun is used, and thus the equipment size can be reduced compared with the Marchand balun. However, in a sub-terahertz band, parasitic capacitance between transformer lines increases, resulting in a deterioration in characteristics.

At high frequencies, such as sub-terahertz frequencies, a line length is greatly shortened, thus enabling downsized and low-loss equipment even when a Marchand balun is used. Thus, in recent years, a Marchand balun has been attracting attention as a transformer suitable for high frequencies, such as sub-terahertz frequencies.

### BRIEF SUMMARY OF THE DISCLOSURE

In a dielectric substrate where a Marchand balun is mounted in a sub-terahertz range, a through hole may be formed that extends from a back surface side of a surface where the balun is mounted to this balun, and a via may be disposed inside this through hole, thus electrically connecting the balun to a ground electrode through this via. At this time, parasitic capacitance at a contact surface between the via and the balun may occur. The parasitic capacitance that has occurred at the contact surface between the via and the balun and the inductance of the balun itself may form an unintended series resonant circuit, and an attenuation pole may occur in a pass band due to this series resonant circuit.

The present disclosure has been made to deal with such an issue and aims to improve bandpass characteristics in a balun used in communication devices.

A balun according to the present disclosure includes: a dielectric substrate having a first surface and a second surface facing each other; a ground electrode formed on the first surface; an unbalanced terminal formed on the second surface; a pair of balanced terminals including a first balanced terminal formed on the second surface; a main line formed on the second surface and having one end connected to the unbalanced terminal and another end being open; a first sub line formed on the second surface and having one end connected to the first balanced terminal; and a second sub line formed on the second surface and having one end connected to the first balanced terminal. The first sub line has another end connected to the ground electrode through a first via and is disposed between the main line and the second sub line. Each of the first sub line and the second sub line overlaps the ground electrode when the second surface is viewed in plan.

A balun according to an aspect includes: a dielectric substrate including multiple layers including a first layer laminated together; a ground electrode formed in the first layer; an unbalanced terminal provided in the dielectric substrate; a pair of balanced terminals including a first balanced terminal provided in the dielectric substrate; a main line formed in a layer different from the first layer and having one end connected to the unbalanced terminal and another end being open; a first sub line formed in a layer different from the first layer and having one end connected to the first balanced terminal; and a second sub line formed in a layer different from the first layer and having one end connected to the first balanced terminal. The first sub line has another end connected to the ground electrode through a first via and is disposed between the main line and the second sub line when viewed from a stacking direction of the dielectric substrate. Each of the first sub line and the second sub line overlaps the ground electrode when viewed from the stacking direction of the dielectric substrate.

According to the present disclosure, in the balun in which the ground electrode and the first sub line are electrically connected, in addition to the first sub line connected to the balanced terminal, the second sub line connected to the balanced terminal is similarly formed. The first sub line is disposed between the main line and the second sub line, and the second sub line is capacitively coupled to the ground electrode through the dielectric substrate. The second sub line whose degree of coupling with the main line is smaller than that of the first sub line is capacitively coupled to the ground electrode to lower a series resonant frequency while suppressing the deterioration of the degree of coupling between the main line and the sub line, making it possible to adjust a frequency at which an attenuation pole occurs. That is, bandpass characteristics can be improved in the balun used in communication devices.

### BRIEF DESCRIPTION OF THE SEVERAL VIEWS OF THE DRAWINGS

FIG. 1 is a block diagram of a communication device including a front-end circuit in which a balun according to an embodiment is used.

FIG. 2 illustrates an example of a circuit diagram of the balun in FIG. 1.

FIG. 3 is a plan view of the balun in Embodiment 1.

FIG. 4 is a diagram illustrating cross sections of an end portion Es2 and an end portion Es3.

FIG. 5 illustrates an equivalent circuit of a sub line SL1 and a sub line SL2 in Embodiment 1.

FIG. 6 illustrates an example of a circuit diagram of a balun in a comparative example.

FIG. 7 is a plan view of the balun in the comparative example.

FIG. 8 is an equivalent circuit diagram illustrating a relationship between the sub line SL1 and a via V1 in the comparative example.

FIG. 9 is a graph illustrating bandpass characteristics of the balun in the comparative example.

FIG. 10 is an enlarged view of insertion loss near a pass band in FIG. 9.

FIG. 11 is a graph illustrating bandpass characteristics of the balun in Embodiment 1.

FIG. 12 is an enlarged view of insertion loss near a pass band in FIG. 11.

FIG. 13 illustrates electric field coupling between wiring patterns in the balun in the comparative example.

FIG. 14 illustrates electric field coupling between wiring patterns in Embodiment 1.

FIG. 15 is a schematic configuration diagram of a communication device in Embodiment 2.

FIG. 16 is a plan view of a balun in Embodiment 3.

### DETAILED DESCRIPTION OF THE DISCLOSURE

Embodiments of the present disclosure will be described in detail below with reference to the drawings. Note that identical or corresponding elements or portions in the drawings are denoted by the same reference signs and a repeated description thereof is not given.

### Embodiment 1

A schematic configuration of a balun 100 and a front-end circuit 10 in Embodiment 1 will be described with reference to FIG. 1.

### Overview of Communication Device

FIG. 1 is a block diagram of a communication device 1000 including the front-end circuit 10 in which the balun 100 according to an embodiment is used. Referring to FIG. 1, the communication device 1000 includes, in addition to the front-end circuit 10, an antenna ANT, and an RFIC 20, which is a signal processing circuit.

The RFIC 20 outputs, to the front-end circuit 10, a radio frequency signal to be radiated from the antenna ANT. The front-end circuit 10 includes, in addition to the balun 100, a matching network 50, and a power amplifier PA. The balun 100, the matching network 50, and the power amplifier PA are disposed within the same dielectric substrate Sb1.

A base material of the dielectric substrate Sb1 is a compound semiconductor. This compound semiconductor is made by an integrated circuit process using, as a material, for example, a semiconductor primarily composed of a compound of group-III and group-V elements. The above-described semiconductor is a semiconductor primarily composed of GaAs (gallium arsenide), for example.

The power amplifier PA amplifies the radio frequency signal transmitted from the RFIC 20 and outputs the signal to the matching network 50. The matching network 50 is provided between the power amplifier PA and the balun 100 and provides impedance matching between the power amplifier PA and the balun 100. The radio frequency signal through matching by the matching network 50 is transmitted to the balun 100.

The balun 100 is a transformer that converts between unbalanced and balanced signals. In Embodiment 1, the balun 100 converts an unbalanced signal to balanced signals. The balanced signals are a pair of signals with equal amplitude and opposite phases to each other. The unbalanced signal is a signal used in a transmission system in which a change in potential with respect to a ground electrode is transmitted. Radio frequency signals converted from an unbalanced signal to balanced signals by the balun 100 are transmitted to the antenna ANT. The antenna ANT is, for example, a patch antenna including feed points Fp1 and Fp2.

The balun 100 includes an unbalanced terminal TU1, and two balanced terminals (balanced terminal TB1 and balanced terminal TB2). A balanced signal converted by the balun 100 and outputted from the balanced terminal TB1 is fed to the feed point Fp1 of the antenna ANT. A balanced signal outputted from the balanced terminal TB2 is fed to the feed point Fp2 of the antenna ANT. The feed points Fp1 and Fp2 are offset from each other in opposite directions in a polarization direction with respect to a center of the antenna ANT, which is a patch antenna. The balun 100 feeds two signals with opposite phases for the same polarization direction.

### Configuration of Balun

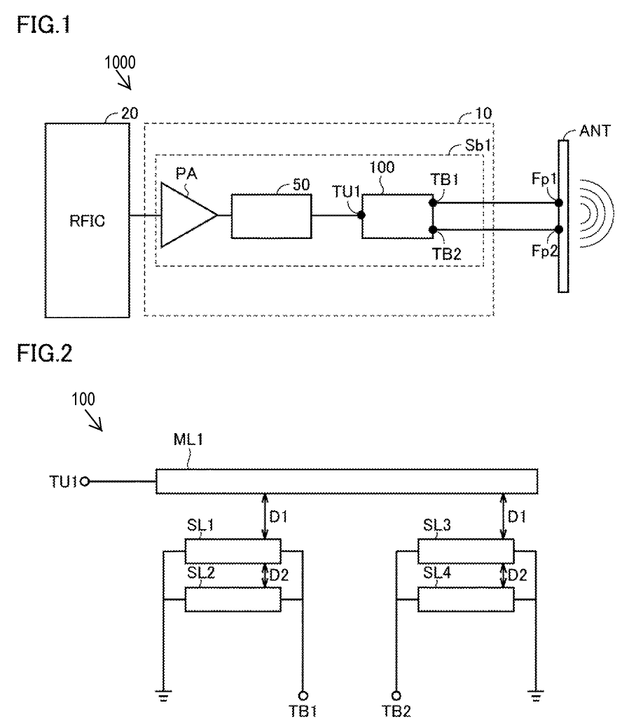

FIG. 2 illustrates an example of a circuit diagram of the balun 100 in FIG. 1. Referring to FIG. 2, the balun 100 includes, in addition to the unbalanced terminal TU1 and the balanced terminals TB1 and TB2, a main line ML1, and sub lines SL1 to SL4. When a wavelength of a radio frequency signal to be passed is denoted by λ, the main line ML1 has an electrical length of λ/2, and each of the sub lines SL1, SL2, SL3, and SL4 has an electrical length of λ/4.

In Embodiment 1, an example will be described where the unbalanced terminal TU1 is used as an input terminal and each of the balanced terminal TB1 and the balanced terminal TB2 is used as an output terminal to convert an unbalanced signal to balanced signals. Note that the balun 100 can also be used to convert balanced signals inputted to the balanced terminal TB1 and the balanced terminal TB2 to an unbalanced signal and output the unbalanced signal from the unbalanced terminal TU1.

A pass band of the balun 100 in Embodiment 1 is a band from 120 GHz to 140 GHz. In an aspect, the pass band of the balun 100 may be another band, such as a band from 130 GHz to 150 GHz or a band from 140 GHz to 160 GHz.

The balun 100 is a so-called Marchand balun in which two sub lines SL1 and SL3 having a length of a quarter of the wavelength λ (λ/4) are coupled to the main line ML1 connected to the unbalanced terminal and having a length of λ/2. In such a Marchand balun, the lengths of the main line ML1 and sub lines SL1 to SL4 are set as appropriate in accordance with a center frequency of the pass band.

As illustrated in FIG. 2, one end of the main line ML1 is connected to the unbalanced terminal TU1, and the other end is open. The sub line SL1 is connected between the balanced terminal TB1 and the ground electrode (reference potential). The sub line SL1 is disposed so as to couple to the main line ML1, which is an unbalanced line, via an electromagnetic field. Similarly, the sub line SL3 is connected between the balanced terminal TB2 and the ground electrode. The sub line SL3 is disposed so as to couple to the main line ML1, which is an unbalanced line, via an electromagnetic field. The sub lines SL1 and SL3 are connected to the ground electrode and the respective balanced terminals TB1 and TB2 so that a radio frequency signal outputted through the sub line SL1 is opposite in phase to a radio frequency signal outputted through the sub line SL3.

In the Marchand balun having such a configuration, a radio frequency signal inputted to the unbalanced terminal TU1 (input terminal) is transmitted to two balanced lines via electromagnetic field coupling and outputted as balanced signals from the balanced terminal TB1 (output terminal) and the balanced terminal TB2 (output terminal).

In Embodiment 1, as illustrated in FIG. 2, the sub line SL2 is connected in parallel with the sub line SL1 between the balanced terminal TB1 and the ground electrode. As illustrated in FIG. 2, the sub line SL4 is connected in parallel with the sub line SL3 between the balanced terminal TB2 and the ground electrode.

As illustrated in FIG. 2, each of a distance between the sub line SL3 and the main line ML1 and a distance between the sub line SL1 and the main line ML1 is a spacing D1. Furthermore, each of a distance between the sub line SL4 and the sub line SL3 and a distance between the sub line SL2 and the sub line SL1 is a spacing D2.

In the balun 100 in this embodiment, the sub lines SL2 and SL4 illustrated in FIG. 2 are provided, enabling a frequency at which an attenuation pole occurs in the pass band to be lowered. As a result, pass band characteristics of the balun 100 can be improved. The main line ML1 can correspond to “main line” in the present disclosure. The sub lines SL1 to SL4 can respectively correspond to “first sub line to fourth sub line” in the present disclosure. The balanced terminal TB1 can correspond to “first balanced terminal” in the present disclosure. The balanced terminal TB2 can correspond to “second balanced terminal” in the present disclosure.

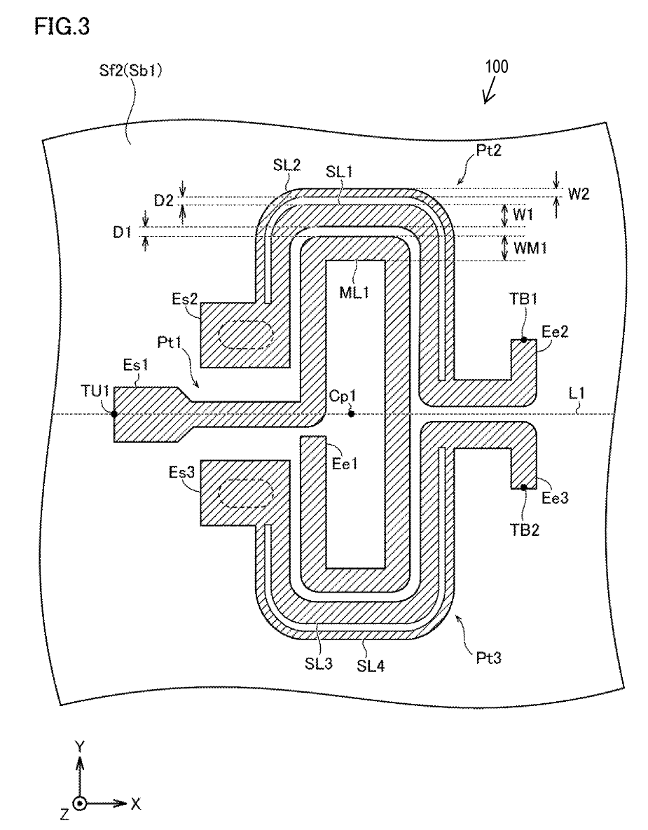

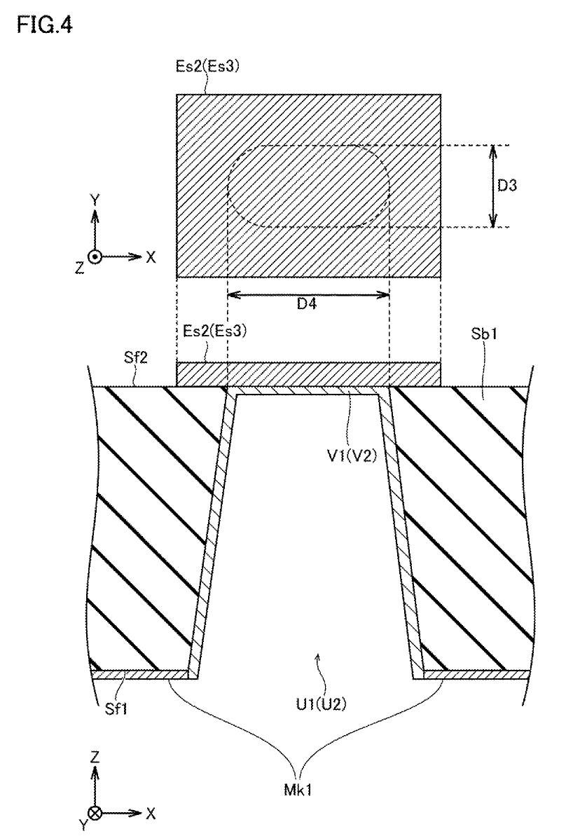

Next, the shape of the balun 100 illustrated in FIG. 2 will be described in detail with reference to FIGS. 3 and 4. FIG. 3 is a plan view of the balun 100 in Embodiment 1. As illustrated in FIG. 3, the balun 100 is formed on the dielectric substrate Sb1. In FIGS. 3 and 4, a normal direction of a main surface Sf1 of the dielectric substrate Sb1 is a Z axis, a certain direction in a plane of the main surface Sf1 is an X axis, and a direction orthogonal to the X axis is a Y axis. FIG. 3 illustrates a main surface Sf2, which is a surface on a Z-axis positive side of the dielectric substrate Sb1. The dielectric substrate Sb1 in Embodiment 1 is a substrate formed by laminating multiple layers. In an aspect, the dielectric substrate Sb1 may be a single-layer substrate.

The main line ML1 and the sub lines SL1 to SL4 that are included in the balun 100 are formed on the main surface Sf2 of the dielectric substrate Sb1. A point Cp1 is a point on the main surface Sf2. The main line ML1 and the sub lines SL1 to SL4 are disposed around the point Cp1. The balun 100 includes a wiring pattern Pt1, a wiring pattern Pt2, and a wiring pattern Pt3.

In Embodiment 1, the main line ML1 described with reference to FIG. 2 is implemented by the wiring pattern Pt1 and end portions Es1 and Ee1 that are illustrated in FIG. 3. Of the wiring patterns Pt1 to Pt3, the wiring pattern Pt1 is disposed closest to the point Cp1. In other words, the wiring pattern Pt1 is disposed furthest within the balun 100. The wiring pattern Pt1 is connected to the unbalanced terminal TU1 at the end portion Es1. As illustrated in FIG. 3, the main line ML1 extends from the end portion Es1 in an X-axis positive direction and then winds clockwise around the Z axis passing through the point Cp1 as a winding axis. In other words, the main line ML1 has a shape wound around the Z axis passing through the point Cp1 when the dielectric substrate Sb1 is viewed in plan. The end portion Ee1 is an open end.

The wiring pattern Pt2 is disposed on a Y-axis positive side with respect to the wiring pattern Pt1. The wiring pattern Pt3 is disposed on a Y-axis negative side with respect to the wiring pattern Pt1. That is, the wiring pattern Pt1 is disposed between the wiring pattern Pt2 and the wiring pattern Pt3. The wiring pattern Pt2 and the wiring pattern Pt3 have shapes that are symmetric with respect to a line L1 illustrated in FIG. 3 as a center line. The line L1 is a line in an X-axis direction passing through the point Cp1.

In Embodiment 1, each of the sub line SL1 and the sub line SL2 described with reference to FIG. 2 is implemented by the wiring pattern Pt2 and end portions Es2 and Ee2 that are illustrated in FIG. 3. The wiring pattern Pt2 is in contact with the ground electrode on a Z-axis negative side with respect to the end portion Es2. A contact area between the end portion Es2 and the ground electrode will be described below with reference to a cross-sectional view in FIG. 4. As illustrated in FIG. 3, the sub line SL1 is disposed along the main line ML1 disposed on the Y-axis positive side relative to the line L1. In other words, the sub line SL1 is substantially J-shaped. The sub line SL1 couples to the main line ML1 disposed on the Y-axis positive side relative to the line L1 via an electromagnetic field. The distance between the sub line SL1 and the main line ML1 is the spacing D1.

The spacing D1 is, for example, a length of 5 µm or more but less than 6 µm. As illustrated in FIG. 3, the spacing D1 is indicated as the distance between the sub line SL1 and the main line ML1 in a Y-axis direction, but the distance between the sub line SL1 and the main line ML1 is the spacing D1 even in the X-axis direction and in a curved portion. That is, the sub line SL1 and the main line ML1 are disposed so that all the distances between the sub line SL1 and the main line ML1 in respective directions are the uniform spacing D1. Furthermore, in other words, the spacing D1 is the shortest distance between a side edge of the sub line SL1 and a side edge of the main line ML1.

As illustrated in FIG. 3, the sub line SL2 is disposed along the sub line SL1. That is, the sub line SL2 is also substantially J-shaped. The distance between the sub line SL2 and the sub line SL1 is the spacing D2. The spacing D2 is, for example, a length of 3 µm or more but less than 5 µm. As with the spacing D1 between the sub line SL1 and the main line ML1, the distance between the sub line SL2 and the sub line SL1 is the spacing D2 not only in the Y-axis direction but also in the X-axis direction and a curved portion. That is, the sub line SL2 and the sub line SL1 are disposed so that all the distances between the sub line SL2 and the sub line SL1 in respective directions are the uniform spacing D2. Furthermore, in other words, the spacing D2 is the shortest distance between a side edge of the sub line SL1 and a side edge of the sub line SL1. Thus, the sub lines SL1 and SL2 are disposed along the shape of the main line ML1. As a result, the sub line SL1 is disposed between the sub line SL2 and the main line ML1.

Thus, the wiring pattern Pt2 is formed so that the spacing D2 is shorter than the spacing D1. The wiring pattern Pt2 is connected to the balanced terminal TB1 at the end portion Ee2. This enables the electrical length of the sub line SL2 to be closer to that of the sub line SL1. If the spacing D2 and the spacing D1 are equal in length, since the sub line SL2 is disposed further out than the sub line SL1, the electrical length of the sub line SL2 is longer than that of the sub line SL1. As a result, one of the sub lines SL1 and SL2 has a length deviating from the length of λ/4. For this reason, in Embodiment 1, the spacing D2 being shorter than the spacing D1 enables the electrical lengths of the sub line SL1 and the sub line SL2 to be closer to the same length, thereby suppressing an increase in deviation from the length of λ/4.

In Embodiment 1, each of the sub line SL3 and the sub line SL4 described with reference to FIG. 2 is implemented by the wiring pattern Pt3 and end portions Es3 and Ee3 that are illustrated in FIG. 3. The wiring pattern Pt3 is in contact with the ground electrode on the Z-axis negative side with respect to the end portion Es3. A contact area between the end portion Es3 and the ground electrode will be described below with reference to the cross-sectional view in FIG. 4. The sub line SL3 is shaped along the main line ML1 disposed on the Y-axis negative side relative to the line L1. In other words, the sub line SL3 is substantially J-shaped.

The distance between the sub line SL3 and the main line ML1 is the spacing D1 as well as the distance between the sub line SL1 and the main line ML1. The sub line SL3 couples to the main line ML1 disposed on the Y-axis negative side relative to the line L1 via an electromagnetic field. The spacing D1 that is the distance between the sub line SL3 and the main line ML1 is the spacing D1 even in the X-axis direction and in a curved portion as well as the distance between the sub line SL1 and the main line ML1. That is, the sub line SL3 and the main line ML1 are disposed so that all the distances between the sub line SL3 and the main line ML1 in respective directions are the uniform spacing D1. Furthermore, in other words, the spacing D1 is the shortest distance between a side edge of the sub line SL3 and the side edge of the main line ML1.

The sub line SL4 is shaped along the sub line SL3. That is, the sub line SL4 is also substantially J-shaped. The distance between the sub line SL4 and the sub line SL1 is the spacing D2. The spacing D2 that is the distance between the sub line SL4 and the sub line SL3 is the spacing D2 even in the X-axis direction and in a curved portion as well as the distance between the sub line SL2 and the sub line SL1. That is, the sub line SL4 and the sub line SL3 are disposed so that all the distances between the sub line SL4 and the sub line SL3 in respective directions are the uniform spacing D2. Furthermore, in other words, the spacing D2 is the shortest distance between a side edge of the sub line SL4 and a side edge of the sub line SL3.

Thus, the wiring pattern Pt3 is also formed so that the spacing D2 is shorter than the spacing D1 as well as the wiring pattern Pt2. The wiring pattern Pt3 is connected to the balanced terminal TB2 at the end portion Ee3. This enables, in Embodiment 1, the electrical lengths of the sub line SL3 and the sub line SL4 to be closer to the same length, thereby suppressing an increase in deviation from the length of λ/4. Furthermore, as described above, the main line ML1 in Embodiment 1 has a shape that winds around the Z axis. This enables the balun 100 to be downsized compared with a case where the main line ML1 is linear without winding.

Referring to FIG. 3, the main line ML1 has a width WM1. The sub line SL1 has a width W1. The sub line SL2 has a width W2.

FIG. 4 is a diagram illustrating cross sections of the end portion Es2 and the end portion Es3. The cross sections of the end portion Es2 and the end portion Es3 in FIG. 3 have similar shapes. Hence, in the following, the end portion Es2 will be used as an example for ease of explanation.

The upper portion of FIG. 4 illustrates a plan view of the end portion Es2 as viewed from the Z-axis positive side illustrated in FIG. 3. The lower portion of FIG. 4 illustrates a cross-sectional view of the end portion Es2 as viewed from the Y-axis negative side. As illustrated in the lower portion of FIG. 4, the dielectric substrate Sb1 has the main surface Sf2 on the Z-axis positive side while having the main surface Sf1 on the Z-axis negative side. In the main surface Sf1 for the end portion Es2, a through hole U1 is formed by etching. At an opening on a main surface Sf2 side of the through hole U1, the end portion Es2 is disposed so as to cover the through hole U1. More specifically, the through hole U1 is a region where the end portion Es2 of the wiring pattern Pt2 is disposed on the Z-axis positive side and an opening is present on the Z-axis negative side.

In the balun 100, the through hole U1 is formed, and then a ground electrode Mk1 is disposed on the main surface Sf1. The ground electrode Mk1 is formed, for example, by plating. In Embodiment 1, plating is also applied to the main surface Sf1 and the inside of the through hole U1. As a result, as illustrated in FIG. 4, a via V1 is formed on an inner surface of the through hole U1. The ground electrode Mk1 and the via V1 are made of the same base material. An electrode formed on the main surface Sf1 is referred to as “ground electrode Mk1”, and an electrode formed inside the through hole U1 is referred to as “via V1”. That is, the via V1 electrically connects the end portion Es2 disposed on the main surface Sf2 to the ground electrode Mk1 disposed on the main surface Sf1. Note that, at the end portion Es3, a via V2 and a through hole U2 are formed as at the end portion Es2.

The ground electrode Mk1 is disposed on the entire main surface Sf1 and is also disposed on the main surface Sf2 below the main line ML1 and the sub lines SL1 and SL2. In other words, each of the main line ML1 and the sub lines SL1 and SL2 overlaps the ground electrode Mk1 when the main surface Sf1 is viewed in plan. That is, capacitive coupling occurs between the main line ML1 and the ground electrode Mk1, capacitive coupling occurs between the sub line SL1 and the ground electrode Mk1, and capacitive coupling occurs between the sub line SL2 and the ground electrode Mk1. These capacitive coupling magnitudes increase as the width WM1 of the main line ML1, the width W1 of the sub line SL1, and the width W2 of the sub line SL2 illustrated in FIG. 3 increase. In Embodiment 1, the width WM1 is equal to the width W1. The width W2 is shorter than the width W1.

In the upper portion of FIG. 4, a substantially elliptical shape indicated by a dashed line represents the opening of the through hole, that is, an area where the ground electrode Mk1 and the end portion Es2 are in contact with each other. A length of this elliptical shape in the Y-axis direction is a length D3. Furthermore, a length of this elliptical shape in the X-axis direction is a length D4. For example, the length D3 is 15 µm, and the length D4 is 30 µm.

Thus, in the balun 100 in this embodiment, the end portion Es2 is connected to the ground electrode Mk1 through the via V1 formed on the Z-axis negative side with respect to the end portion Es2. However, it is difficult to bring the via V1 formed inside the through hole U1 by plating and the end portion Es2 in full contact with each other, and a very small capacitance component may be generated between the via V1 and the end portion Es2. This causes unintended parasitic capacitance to occur between the end portion Es2 and the via V1.

When parasitic capacitance occurs between the ground electrode Mk1 and the end portion Es2, an LC series resonator is formed by a capacitance component of this parasitic capacitance and inductance components of the sub line SL1 and the sub line SL2. As a result, in the balun 100, a part of an unbalanced signal flows into the ground electrode Mk1 at a resonant frequency of this LC series resonator. When the resonant frequency of the LC series resonator is a frequency within the pass band, bandpass characteristics of the balun 100 decrease. Thus, in the balun 100 in Embodiment 1, the sub lines SL2 and SL4 are provided to lower the resonant frequency of the LC series resonator formed by the capacitance component between the ground electrode Mk1 and the end portion Es2, thereby keeping the bandpass characteristics of the balun 100 from decreasing.

FIG. 5 illustrates an equivalent circuit of the sub line SL1, the sub line SL2, and the via V1 in Embodiment 1. FIG. 5 illustrates the sub line SL1, the sub line SL2, a load RL, which is the load impedance of the antenna ANT, and the via V1. As illustrated in FIG. 5, the unintended parasitic capacitance described above is represented as capacitance CX1 at one end of the sub line SL1. The load RL is connected to the other end of the sub line SL1. In FIG. 5, a capacitance component generated between the sub line SL1 and the ground electrode Mk1, which are positioned so as to overlap each other when the main surface Sf1 is viewed in plan, is represented as capacitance Cs2. As described above, the capacitance value of the capacitance Cs2 increases as the width W1 increases.

The balun 100 in Embodiment 1 includes the sub line SL2 in addition to the sub line SL1. As a result, capacitance Cs3 also occurs between the sub line SL2 and the ground electrode Mk1 applied to the main surface Sf1. As with the capacitance Cs2, the capacitance Cs3 is a capacitance component generated between the sub line SL2 and the ground electrode Mk1. As described above, the capacitance value of the capacitance Cs3 increases as the width W2 increases. In Embodiment 1, this capacitance Cs3 can increase a capacitance component of the LC series resonator formed by the capacitance CX1 of the parasitic capacitance and the inductance components of the sub line SL1 and the sub line SL2. This enables, in Embodiment 1, the resonant frequency of the LC series resonator to be lowered compared with a configuration in which no sub line SL2 is provided.

### Comparative Example

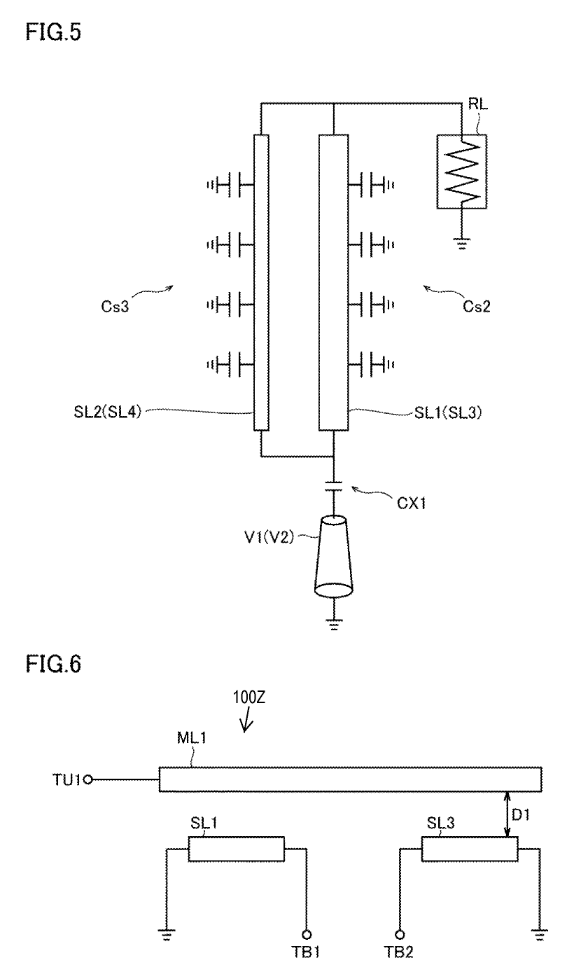

FIG. 6 illustrates an example of a circuit diagram of a balun 100Z in a comparative example. The balun 100Z in FIG. 6 is a typical Marchand balun and is constructed by removing the sub line SL2 and the sub line SL4 from the balun 100 in Embodiment 1.

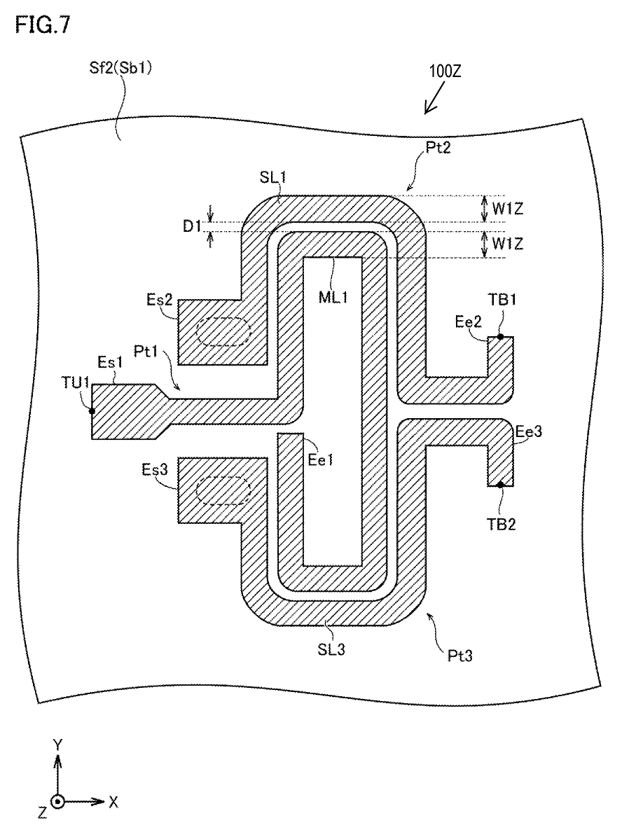

FIG. 7 is a plan view of the balun 100Z in the comparative example. As illustrated in FIG. 7, the wiring patterns Pt2 and Pt3 in the comparative example have shapes obtained by removing the sub lines SL2 and SL4 from the wiring patterns Pt2 and Pt3 in Embodiment 1. That is, the wiring patterns Pt2 and Pt3 in the balun 100Z in the comparative example have only the sub lines SL1 and SL3, respectively. As illustrated in FIG. 7, in the balun 100Z in the comparative example, a width W1Z of the main line ML1 is equal to a width W1Z of the sub line SL1.

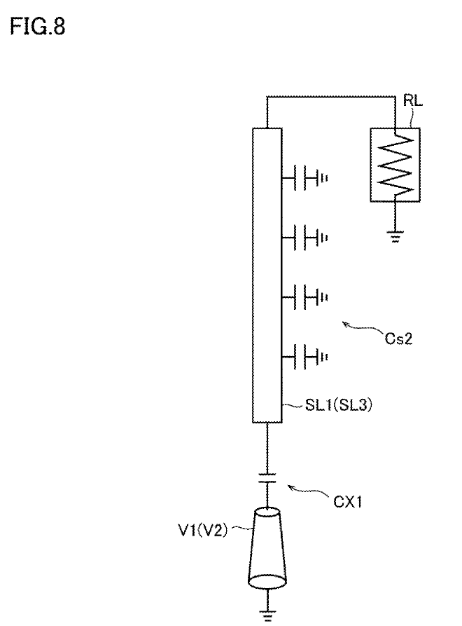

FIG. 8 is an equivalent circuit diagram illustrating a relationship between the sub line SL1 and the via V1 in the comparative example. Since the sub line SL2 is removed in the comparative example, a capacitance component connected in parallel with the ground electrode Mk1 between the via V1 and the load RL is only the capacitance Cs2 between the sub line SL1 and the ground electrode Mk1. In the comparative example, an attenuation pole is generated due to a resonant frequency of an LC series resonator formed by the capacitance CX1 of the parasitic capacitance and the inductance component of the sub line SL1.

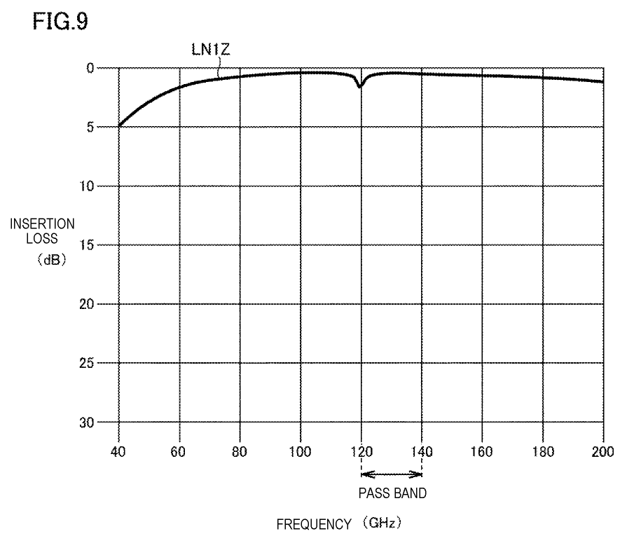

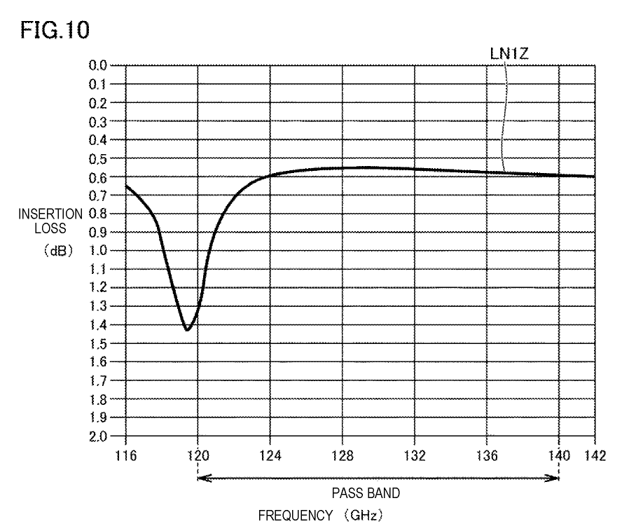

FIG. 9 is a graph illustrating bandpass characteristics of the balun 100Z in the comparative example. In FIG. 9, the horizontal axis represents frequency, and the vertical axis represents insertion loss of the balun 100Z. FIG. 10 is an enlarged view of insertion loss near a pass band in FIG. 9. In FIGS. 9 and 10, insertion loss in the balun 100Z in the comparative example is indicated by a solid line LN1Z. As illustrated in FIG. 10, in the balun 100 in Embodiment 1, an attenuation pole is generated near 119 GHz on a low-frequency side with respect to the pass band. This attenuation pole is generated by the LC series resonator formed by the capacitance CX1 of the parasitic capacitance and the inductance component of the sub line SL1 that are described above. As a result, as illustrated in FIG. 10, an effect of this attenuation pole occurs within the pass band of the balun 100Z, and the bandpass characteristics of the balun 100Z are reduced.

### Bandpass Characteristics in Embodiment 1

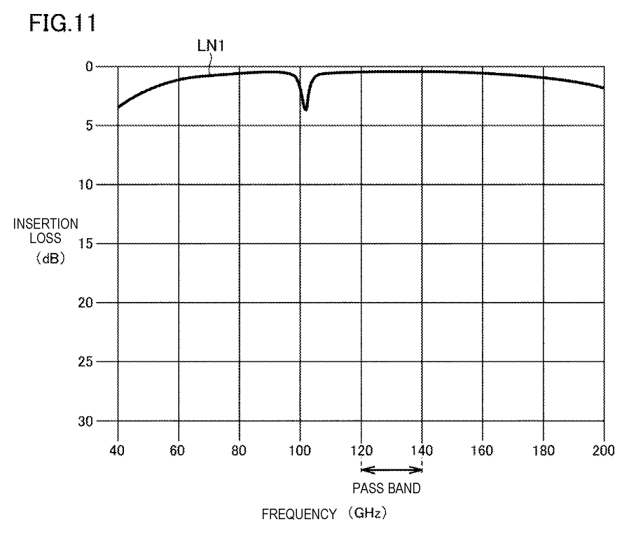

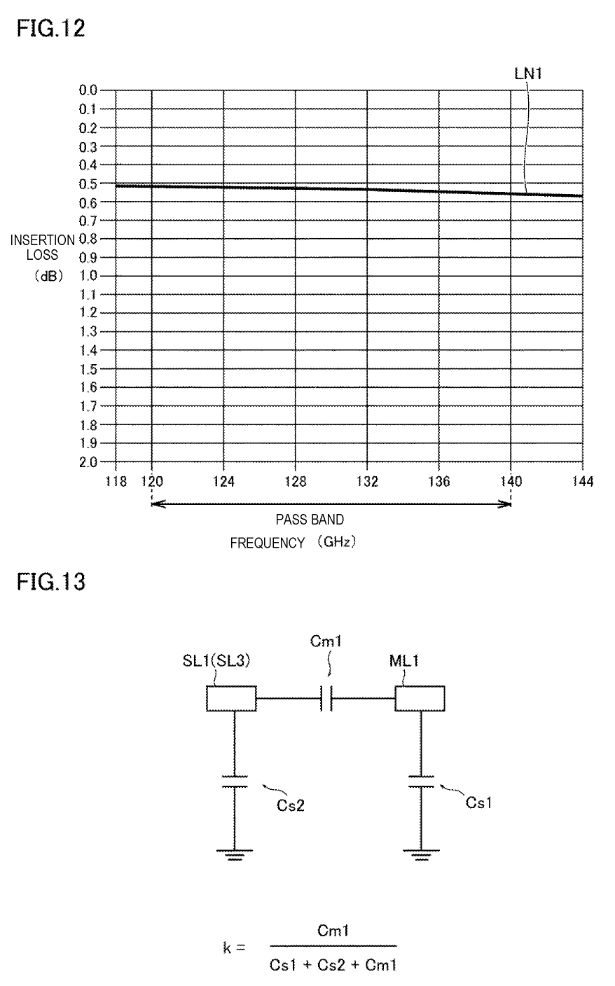

FIG. 11 is a graph illustrating the bandpass characteristics of the balun 100 in Embodiment 1. In FIGS. 11 as well as in 6 , the horizontal axis represents frequency, and the vertical axis represents insertion loss of the balun 100. FIG. 12 is an enlarged view of insertion loss near a pass band in FIG. 11. In FIGS. 11 and 12, insertion loss in the balun 100 in Embodiment 1 is indicated by a solid line LN1.

As illustrated in FIG. 11, in the balun 100 in Embodiment 1, an attenuation pole is generated near 102 GHz on a low-frequency side with respect to the pass band. As described above, this attenuation pole is generated by the LC series resonator formed by the capacitance CX1 of the parasitic capacitance and the inductance components of the sub line SL1 and the sub line SL2 that are described above. However, in the balun 100 in Embodiment 1, when the sub line SL2 is provided, the capacitance Cs3 occurs to increase the capacitance component of the LC series resonator, thereby shifting a frequency of the attenuation pole to a low-frequency range.

Thus, in the balun 100 in Embodiment 1, the sub line SL2 is provided to lower the resonant frequency of the LC series resonator, which is unintentionally formed, thereby shifting the attenuation pole to a lower frequency band than the pass band. As a result, in Embodiment 1, no attenuation pole is generated within the pass band as illustrated in FIG. 12. That is, the bandpass characteristics are improved in the balun 100 used in the communication device 1000. Although the effect of providing the sub line SL2 in the wiring pattern Pt2 has been described above, a similar effect is achieved by providing the sub line SL4 in the wiring pattern Pt3. In Embodiment 1, as an example, the case has been described in which the wiring patterns Pt2 and Pt3 have the sub lines SL2 and SL4, respectively, but the sub line SL2 or the sub line SL4 may be provided in only one of the wiring patterns Pt2 and Pt3.

As indicated by the comparison between Embodiment 1 and the comparative example in FIGS. 8 to 12, in Embodiment 1, the capacitance Cs3 occurring due to the provision of the sub line SL2 is added to the capacitance component of the LC series resonator. In particular, when comparing FIGS. 5 and 8, in Embodiment 1, the capacitance Cs3 illustrated in FIG. 5 enables the attenuation pole due to the LC series resonator to be shifted to the low-frequency range, thereby improving the bandpass characteristics. Next, an advantage of Embodiment 1 will be described in terms of a coupling coefficient k of electric field coupling between the wiring pattern Pt1 and the wiring pattern Pt2.

### Coupling Coefficient of Electric Field Coupling

FIG. 13 illustrates electric field coupling between the wiring patterns Pt1 and Pt2 in the balun 100Z in the comparative example. The wiring pattern Pt1 and the wiring pattern Pt2 that are described above couple to each other via an electric field. A coupling coefficient k of electric field coupling between wiring patterns is typically determined by line capacitance Cs1, line capacitance Cs2, and line-to-line capacitance Cm1 between the main line ML1 and the sub line SL1 as illustrated in FIG. 13.

The line capacitance Cs1 is a capacitance component between the main line ML1 and the ground electrode Mk1. The line capacitance Cs2 is a capacitance component between the sub line SL1 and the ground electrode Mk1. As described above, in the comparative example, both the width of the main line ML1 and the width of the sub line SL1 are the width W1Z. Hence, a value of the line capacitance Cs1 and a value of the line capacitance Cs2 are equal. The line-to-line capacitance Cm1 is a capacitance component between the sub line SL1 and the main line ML1.

As illustrated in FIG. 13, in the balun 100Z in the comparative example, the coupling coefficient k between the wiring pattern Pt1 and the wiring pattern Pt2 is a value obtained by dividing the line-to-line capacitance Cm1 between the sub line SL1 and the main line ML1 by the sum of the line-to-line capacitance Cm1, the line capacitance Cs1, and the line capacitance Cs2.

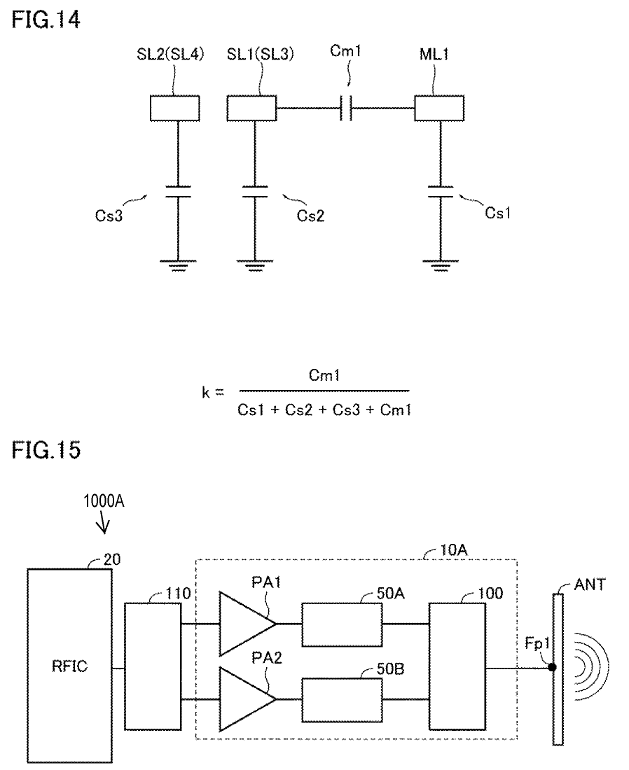

Next, electric field coupling in Embodiment 1 will be described. FIG. 14 illustrates electric field coupling between wiring patterns in Embodiment 1. In the balun 100 in Embodiment 1, the sub line SL2 is provided. Line capacitance Cs3 is a capacitance component between the subline SL2 and the ground electrode Mk1. The coupling coefficient k between the wiring pattern Pt1 and the wiring pattern Pt2 is a value obtained by dividing the line-to-line capacitance Cm1 between the sub line SL1 and the main line ML1 by the sum of the line-to-line capacitance Cm1, the line capacitance Cs1, the line capacitance Cs2, and the line capacitance Cs3.

The line capacitance Cs2 and the line capacitance Cs3 in FIG. 14 correspond to the capacitance Cs2 and the capacitance Cs3 in FIG. 5. As described above, in Embodiment 1, the width WM1 of the main line ML1 and the width W1 of the sub line SL1 are equal. Hence, the line capacitance Cs1 and the line capacitance Cs2 in FIG. 14 have the same value. On the other hand, the width W2 of the sub line SL2 is shorter than the width WM1 and the width W1. Thus, the line capacitance Cs3 has a smaller value than the line capacitance Cs1.

In the Marchand balun described with reference to FIGS. 1 to 5, the bandpass characteristics of the balun 100 are improved by lowering the resonant frequency of the LC series resonator due to the unintentionally generated capacitance CX1. However, in the Marchand balun in Embodiment 1, it is undesirable to change the coupling coefficient k from the same coupling coefficient k as in the balun 100Z in the comparative example. When the coupling coefficient k between the wiring patterns Pt1 and Pt2 decreases, the characteristics in the pass band decrease. Furthermore, when the coupling coefficient k between the wiring patterns Pt1 and Pt2 increases, the width of the main line ML1 or the sub line SL1 is reduced, resulting in increased losses occurring in the main line ML1 or the sub line SL1.

Thus, in the balun 100 in Embodiment 1, as described with reference to FIGS. 2 and 3, the sub line SL1 is disposed between the sub line SL2 and the main line ML1. As a result, the coupling coefficient k in Embodiment 1 varies by the addition of the line capacitance Cs3 to the denominator compared with the coupling coefficient k in the comparative example 1. In the configuration in the comparative example 1, the capacitance component of the LC series resonator can be increased by increasing the width W1Z of the sub line SL1, but the width W1Z of the sub line SL1 affects the line-to-line capacitance Cm1 between the sub line SL1 and the main line ML1, thereby resulting in a substantial change in the coupling coefficient k from the coupling coefficient k illustrated in FIG. 13.

Thus, in Embodiment 1, the width WM1 of the main line ML1 and the width W1 of the sub line SL1 are made equal to each other, and the sub line SL2 different from the sub line SL1 is added. As a result, in Embodiment 1, the resonant frequency of the LC series resonator can be lowered while minimizing a change in the coupling coefficient k. Furthermore, when a change in the value of the coupling coefficient k in Embodiment 1 from the value of the coupling coefficient k in the comparative example 1 is small, the width W1 of the sub line SL1 does not have to be equal to the width WM1 of the main line ML1. For example, the width W1 of the sub line SL1 may be smaller than the width WM1 of the main line ML1 and larger than the width W2 of the sub line SL3. The sizes of the width WM1 and the widths W1 and W2 can be adjusted as appropriate by simulations, experimentation, etc. Thus, in the balun 100 in Embodiment 1, the sub line SL2 is provided separately from the sub line SL1 to lower the LC series resonant frequency while suppressing the deterioration of the degree of coupling between the main line ML1 and the sub line SL1, thereby making it possible to adjust the frequency at which the attenuation pole occurs. That is, the bandpass characteristics of the balun 100 can be improved.

In the example described above, although the wiring patterns Pt1 to Pt3 are disposed in the same layer on the dielectric substrate Sb1, the wiring patterns Pt1 to Pt3 are not limited to this configuration. Each of the wiring patterns Pt1 to Pt3 may be provided in a different layer within the dielectric substrate Sb1, which is composed of multiple layers. Furthermore, each of the wiring patterns Pt1 to Pt3 may be formed as an electrode extending through multiple layers. That is, in Embodiment 1, layers where the main line ML1, the sub lines SL1 and SL2, the ground electrode Mk1, the balanced terminals TB1 and TB2, and the unbalanced terminal TU1 are formed may be layers different from one another as long as the line capacitance Cs2 and the line capacitance Cs3 are generated by the sub lines SL1 and SL2 overlapping the ground electrode Mk1 when viewed from the stacking direction of the dielectric substrate Sb1.

More specifically, if the dielectric substrate Sb1 is formed by laminating four layers, which are a first layer, a second layer, a third layer, and a fourth layer, the ground electrode Mk1 may be formed in the first layer, the main line ML1 may be formed in the second layer, the sub line SL1 may be formed in the third layer, and the sub line SL2 may be formed in the fourth layer. In this case as well, the sub line SL1 is formed between the main line ML1 and the sub line SL2, and thus the degree of coupling between the sub line SL2 and the main line ML1 is less than the degree of coupling between the sub line SL1 and the main line ML1.

### Embodiment 2

A schematic configuration of the balun 100 and a front-end circuit 10A in Embodiment 2 will be described with reference to FIG. 15. FIG. 15 is a schematic configuration diagram of a communication device 1000A in Embodiment 2. In Embodiment 2, a description of configurations similar to those in Embodiment 1 will not be repeated.

The communication device 1000A in Embodiment 2 includes, between the RFIC 20 and the front-end circuit 10A, a transformer 110 composed of an MCT element or a balun. The transformer 110 converts an unbalanced signal to balanced signals and outputs the signals to the front-end circuit 10A.

The front-end circuit 10A in Embodiment 2 includes power amplifiers PA1 and PA2, and matching networks 50A and 50B. The power amplifiers PA1 and PA2 amplify the unbalanced signals converted by the transformer 110 and output the signals to the respective matching networks 50A and 50B.

The matching network 50A is provided between the power amplifier PA1 and the balun 100 and provides impedance matching between the power amplifier PA1 and the balun 100. The matching network 50B is provided between the power amplifier PA2 and the balun 100 and provides impedance matching between the power amplifier PA2 and the balun 100. Unlike Embodiment 1, in Embodiment 2, the balun 100 converts balanced signals to an unbalanced signal. A radio frequency signal converted from balanced signals to an unbalanced signal by the balun 100 in Embodiment 2 is transmitted to the feed point Fp1 of the antenna ANT.

Thus, the balun 100 in this embodiment can also be used for the balun 100 that converts balanced signals to an unbalanced signal. In Embodiment 2, as in Embodiment 1, the sub line SL2 is provided separately from the sub line SL1 to lower the LC series resonant frequency while suppressing the deterioration of the degree of coupling between the main line ML1 and the sub line SL1, thereby making it possible to adjust the frequency at which the attenuation pole occurs. That is, the bandpass characteristics of the balun 100 can be improved.

### Embodiment 3

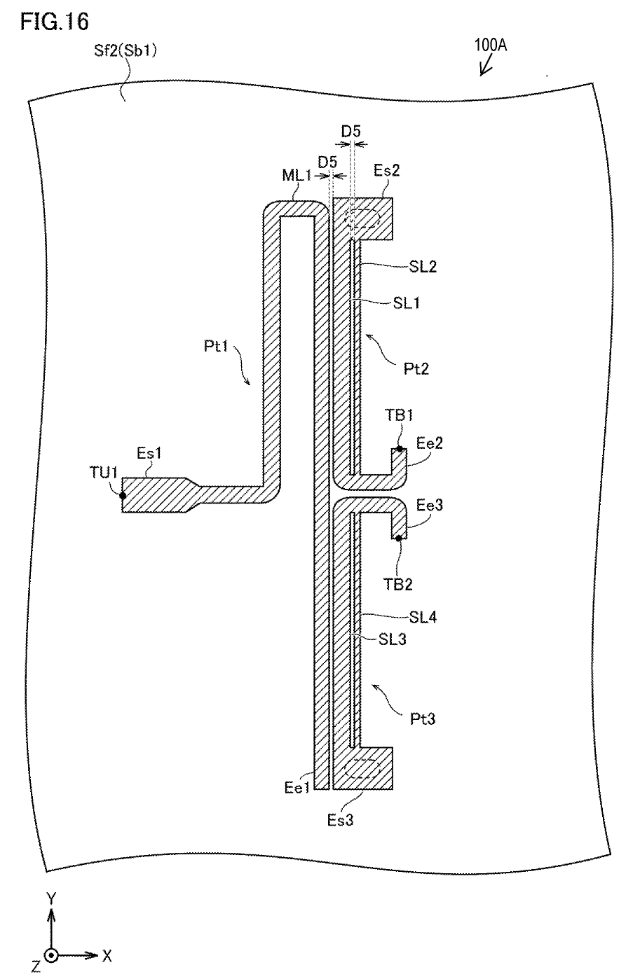

A configuration of a balun 100A in Embodiment 3 will be described with reference to FIG. 16. FIG. 16 is a plan view of the balun 100A in Embodiment 3. In Embodiment 3, a description of configurations similar to those in Embodiment 1 will not be repeated.

In Embodiment 3, the main line ML1 has a linear shape as illustrated in FIG. 16. The sub lines SL1 and SL2 are shaped along the main line ML1 and therefore have a linear shape as well as the main line ML1. Even in such a shape, in the balun 100A in Embodiment 3, the sub line SL2 is provided separately from the sub line SL1 to lower the LC series resonant frequency while suppressing the deterioration of the degree of coupling between the main line ML1 and the sub line SL1, thereby making it possible to adjust the frequency at which the attenuation pole occurs. That is, the bandpass characteristics of the balun 100A can be improved.

Furthermore, in Embodiment 3, since both the sub lines SL1 and SL2 have a linear shape, the spacing between the sub line SL2 and the sub line SL1 does not have to be smaller than the spacing between the main line ML1 and the sub line SL1. For this reason, as illustrated in FIG. 16, in Embodiment 3, the spacing between the sub line SL1 and the sub line SL2 is a spacing D5, which is equal to the spacing between the main line ML1 and the sub line SL1. Furthermore, in Embodiment 3, the main line ML1 has a linear shape extending in the Y-axis direction, and thus the length of the entire balun 100A in the X-axis direction is reduced. As indicated in Embodiments 1 and 3, the design flexibility of the balun 100 can be enhanced by varying the shapes of the main line ML1, and the sub lines SL1 and SL2.

### Appendix 1

A balun comprising: a dielectric substrate having a first surface and a second surface facing each other; a ground electrode formed on the first surface; an unbalanced terminal formed on the second surface; a pair of balanced terminals including a first balanced terminal formed on the second surface; a main line formed on the second surface and having one end connected to the unbalanced terminal and another end being open; a first sub line formed on the second surface and having one end connected to the first balanced terminal; and a second sub line formed on the second surface and having one end connected to the first balanced terminal, wherein the first sub line has another end connected to the ground electrode through a first via and is disposed between the main line and the second sub line, and wherein each of the first sub line and the second sub line overlaps the ground electrode when the second surface is viewed in plan.

### Appendix 2

The balun according to Appendix 1, wherein the main line has a shape wound around a winding axis when the second surface is viewed in plan.

### Appendix 3

The balun according to Appendix 2, wherein a shortest distance between the main line and the first sub line is longer than a shortest distance between the first sub line and the second sub line.

### Appendix 4

The balun according to Appendix 1, wherein the main line has a linear shape when the second surface is viewed in plan.

### Appendix 5

The balun according to Appendix 4, wherein a shortest distance between the main line and the first sub line is equal to a shortest distance between the first sub line and the second sub line.

### Appendix 6

The balun according to any one of Appendices 1 to 5, wherein a width of the first sub line is equal to a width of the main line when the second surface is viewed in plan.

### Appendix 7

The balun according to any one of Appendices 1 to 6, wherein a width of the second sub line is smaller than the width of the first sub line when the second surface is viewed in plan.

### Appendix 8

The balun according to any one of Appendices 1 to 7, wherein a base material of the dielectric substrate is a compound semiconductor.

### Appendix 9

The balun according to any one of Appendices 1 to 8, wherein the pair of balanced terminals includes a second balanced terminal formed on the second surface, wherein the balun further comprises: a third sub line formed on the second surface and having one end connected to the second balanced terminal; and a fourth sub line formed on the second surface and having one end connected between the second balanced terminal and the ground electrode, wherein the third sub line has another end connected to the ground electrode through a second via and is disposed between the main line and the fourth sub line, and wherein each of the third sub line and the fourth sub line overlaps the ground electrode when the first surface is viewed in plan.

### Appendix 10

A front-end circuit comprising: the balun according to Appendix 9; and an amplifier connected to at least one of the first balanced terminal, the second balanced terminal, and the unbalanced terminal, wherein the amplifier is formed on the dielectric substrate.

### Appendix 11

A balun comprising: a dielectric substrate including multiple layers including a first layer laminated together; a ground electrode formed in the first layer; an unbalanced terminal provided in the dielectric substrate; a pair of balanced terminals including a first balanced terminal provided in the dielectric substrate; a main line formed in a layer different from the first layer and having one end connected to the unbalanced terminal and another end being open; a first sub line formed in a layer different from the first layer and having one end connected to the first balanced terminal; and a second sub line formed in a layer different from the first layer and having one end connected to the first balanced terminal, wherein the first sub line has another end connected to the ground electrode through a first via and is disposed between the main line and the second sub line when viewed from a stacking direction of the dielectric substrate, and wherein each of the first sub line and the second sub line overlaps the ground electrode when viewed from the stacking direction of the dielectric substrate.

The embodiments disclosed here are considered to be illustrative and not restrictive in any respect. The scope of the present disclosure is defined not by the above description, but by the claims, and is intended to include all changes made within the meaning and scope equivalent to the claims.

1000, 1000A communication device, ANT antenna, CX1, Cs1 to Cs3 capacitance, Cm1 line-to-line capacitance, Cp1 point, D1, D2, D5 spacing, D3, D4 length, Ee1, Ee2, Ee3 Es1, Es2, Es3 end portion, Fp1, Fp2 feed point, L1 line, LN1Z, LN1 solid line, ML1 main line, Mk1 ground electrode, PA, PA1, PA2 power amplifier, Pt1 to Pt3 wiring pattern, SL1 to SL4 sub line, Sb1 dielectric substrate, Sf1, Sf2 main surface, TB1, TB2 balanced terminal, TU1 unbalanced terminal, U1 through hole, V1 via, W1Z, W1, W2, WM1 width, k coupling coefficient

1. A balun comprising:
a dielectric substrate having a first surface and a second surface facing each other;
a ground electrode on the first surface;
an unbalanced terminal on the second surface;
a pair of balanced terminals including a first balanced terminal formed on the second surface;
a main line on the second surface and having a first end connected to the unbalanced terminal and a second end that is open;
a first sub line on the second surface and having a first end connected to the first balanced terminal; and
a second sub line on the second surface and having a first end connected to the first balanced terminal,
wherein the first sub line has a second end connected to the ground electrode through a first via, and is disposed between the main line and the second sub line, and
wherein each of the first sub line and the second sub line overlaps the ground electrode when the second surface is viewed in plan.

2. The balun according to claim 1, wherein the main line is wound around a winding axis when the second surface is viewed in plan.

3. The balun according to claim 2, wherein a shortest distance between the main line and the first sub line is longer than a shortest distance between the first sub line and the second sub line.

4. The balun according to claim 1, wherein the main line has a linear shape when the second surface is viewed in plan.

5. The balun according to claim 4, wherein a shortest distance between the main line and the first sub line is equal to a shortest distance between the first sub line and the second sub line.

6. The balun according to claim 1, wherein a width of the first sub line is equal to a width of the main line when the second surface is viewed in plan.

7. The balun according to claim 1, wherein a width of the second sub line is smaller than the width of the first sub line when the second surface is viewed in plan.

8. The balun according to claim 1, wherein a base material of the dielectric substrate is a compound semiconductor.

9. The balun according to claim 1,
wherein the pair of balanced terminals includes a second balanced terminal on the second surface,
wherein the balun further comprises:
a third sub line on the second surface and having a first end connected to the second balanced terminal; and
a fourth sub line on the second surface and having a first end connected between the second balanced terminal and the ground electrode,
wherein the third sub line has a second end connected to the ground electrode through a second via, and is disposed between the main line and the fourth sub line, and
wherein each of the third sub line and the fourth sub line overlaps the ground electrode when the first surface is viewed in plan.

10. A front-end circuit comprising:
the balun according to claim 9; and
an amplifier connected to at least one of the first balanced terminal, the second balanced terminal, or the unbalanced terminal,
wherein the amplifier is on the dielectric substrate.

11. A balun comprising:
a dielectric substrate comprising a plurality of layers laminated together, the plurality of layers including a first layer;
a ground electrode in the first layer;
an unbalanced terminal in the dielectric substrate;
a pair of balanced terminals including a first balanced terminal in the dielectric substrate;
a main line in a layer different from the first layer, and having a first end connected to the unbalanced terminal and a second end that is open;
a first sub line in a layer different from the first layer and having a first end connected to the first balanced terminal; and
a second sub line in a layer different from the first layer, and having a first end connected to the first balanced terminal,
wherein the first sub line has a second end connected to the ground electrode through a first via, and is disposed between the main line and the second sub line when viewed from a stacking direction of the plurality of layers of the dielectric substrate, and
wherein each of the first sub line and the second sub line overlaps the ground electrode when viewed from the stacking direction.
